(19) United States
(12) Patent Application Publication
(10) Pub. No.: US 2009/0257203 A1
(43) Pub. Date: Oct. 15, 2009

(54) MOBILE COMMUNICATION DEVICE WITH REPLACEABLE FUNCTIONAL MODULES

(76) Inventors: Sea-Weng YOUNG, Taipei County (TW); Po-Cheng Chen, Taipei County (TW); Kung-Ming Kao, Taipei County (TW)

Correspondence Address: Muncy, Geissler, Olds & Lowe, PLLC, P.O. BOX 1364, FAIRFAX, VA, 22038-1364, US

(21) Appl. No.: 12/422,794

(22) Filed: Apr. 13, 2009

(30) Foreign Application Priority Data
Apr. 14, 2008 (TW) 097113522

(51) Int. Cl. H05K 7/00

(52) U.S. Cl. 361/729

(57) ABSTRACT

A mobile communication device with replaceable function modules includes a main body and an externally connected device. The main body serves as a central member, and has a main hybrid joint including an electrical contact and a magnetic joint. The main hybrid joint of the main body is joined to a device hybrid joint of the externally connected device, so as to realize the function thereof. When joined together, the main body activates a functional module of the externally connected device functional module. In addition, the main body and the externally connected device are further joined through the magnetic joints. Therefore, when separated by accidentally falling onto the ground, the mobile communication device can be rejoined through the magnetic joints, and thus it is unnecessary to worry about the unavailability due to the break-down of the joint portion.

### CROSS-REFERENCE TO RELATED APPLICATION

This application claims the benefit of Taiwan Patent Application No. 097113522, filed on Apr. 14, 2008, which is hereby incorporated by reference for all purposes as if fully set forth herein.

### BACKGROUND OF THE INVENTION

1. Field of Invention

The present invention relates to a mobile communication device with replaceable function modules, and more particularly to a mobile communication device capable of externally connecting a functional module by replacing the external connected device.

2. Related Art

Along with the increasing popularization of the technology, the mobile communication device with various functions emerges quickly in succession and gradually becomes an indispensable part in the modern life. Currently, for a common mobile communication device, no matter in a folded, slide, or integrally formed type, the functional modules and content programs configured therein are all fixed, and it is only possible to download different function programs to realize corresponding operations at the most.

In addition, the mobile communication device may only externally connect with a few types of devices, for example, an earphone, a Bluetooth transmitter, and a microphone, and their configured functional modules fail to enable a keyboard, a mouse, or other devices of a personal computer to be replaced at will. Moreover, when the mobile communication device in use accidentally drops to the ground, a joint portion formed by a catch structure is easily broken to cause unavailability and result in great difficulty in using.

### SUMMARY OF THE INVENTION

Accordingly, the present invention is directed to a mobile communication device with replaceable function modules by connecting a functional module externally through the peripherally arranged hybrid joints.

In order to solve the above problems, in an embodiment of the present invention, a mobile communication device with replaceable function modules is provided. The mobile communication device includes a main body formed by a screen, a processor, and a radio frequency (RF) input/output module. The screen and the RF input/output module are coupled to the processor. The main body further includes at least one main hybrid joint coupled to the processor. The main hybrid joint includes an electrical contact for transmitting signals and a magnetic joint with magnetic properties.

In another embodiment of the present invention, a mobile communication device with replaceable function modules is provided. The mobile communication device includes a main body and a first combining device. The main body includes a screen, a processor, an RF input/output module, and at least one main hybrid joint. The screen, the RF input/output module, and the main hybrid joint are coupled to the processor, and the main hybrid joint includes an electrical contact and a magnetic joint. The first combining device has at least one first hybrid joint. The first hybrid joint includes an electrical contact and a magnetic joint, and is magnetically joined to and electrically coupled to the main body.

In still another embodiment of the present invention, a mobile communication device with replaceable function modules is provided. The mobile communication device includes a main body, a first combining device, and a second combining device. The main body includes a screen, a processor, an RF input/output module, and at least one main hybrid joint. The screen, the RF input/output module, and the main hybrid joint are coupled to the processor, and the main hybrid joint includes an electrical contact, a magnetic joint, and a first positioning member. The first combining device includes at least one first hybrid joint. The first hybrid joint includes an electrical contact, a magnetic joint, and a second positioning member, and the first hybrid joint is magnetically joined to and electrically coupled to the main body. The second combining device includes at least one second hybrid joint. The second hybrid joint includes an electrical contact, a magnetic joint, and a third positioning member, and the second hybrid joint is magnetically joined to and electrically coupled to the main body or the first combining device.

The mobile communication device with replaceable function modules provided by the present invention may be a mobile phone or a personal digital assistant (PDA). The first combining device or the second combining device may be a press-key panel, a multimedia playing controller, a game controller, a loudspeaker, a memory expansion device, or a second electric power supply device upon actual requirements. The first combining device, the second combining device, and the main body are joined with one another by means of lap joint. Besides joined to the main body, the first combining device and the second combining device may also be magnetically joined to and electrically coupled to each other through the hybrid joints thereof by means of lap joint.

In the mobile communication device with replaceable function modules according to an embodiment of the present invention, the main body serving as the central member can be coupled to different devices upon actual requirements. When coupled to an externally connected device, the main body activates a functional module of the externally connected device for operation. Further, the main body is joined to the externally connected device through the magnetic joint and/or the positioning member. When separated by accidentally falling onto the ground, the mobile communication device can be rejoined through the magnetic joints, and thus it is unnecessary to worry about the unavailability due to the break-down of the joint portion. In addition, the main body and the externally connected devices or the externally connected devices are lap-joined to each other, so as to obtain the device capable of externally connecting working modules.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a mobile communication device with replaceable function modules according to an embodiment of the present invention;

FIG. 2A is a schematic view of externally connected devices of a mobile communication device with replaceable function modules according to an embodiment of the present invention;

FIG. 2B is a schematic view of externally connected devices of a mobile communication device with replaceable function modules according to an embodiment of the present invention; and

FIG. 3 is a block diagram of a mobile communication device with replaceable function modules according to an embodiment of the present invention.

### DETAILED DESCRIPTION OF THE INVENTION

In order to have a further understanding of the content of the present invention, a detailed description is given below by embodiments with the accompanying drawings.

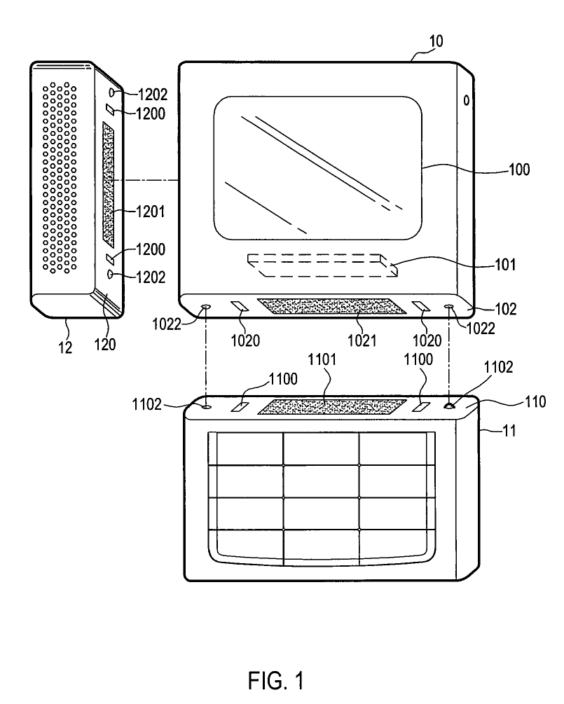

FIG. 1 is a schematic view of a mobile communication device with replaceable function modules according to an embodiment of the present invention. In FIG. 1, the mobile communication device of this embodiment includes a main body 10, a first combining device 11, and a second combining device 12. The main body 10 includes a screen 100, a cell 101, and at least one main hybrid joint 102. The cell 101 may provide an electric power.

The screen 100 may be a touch panel. The main hybrid joint 102 includes an electrical contact 1020 and a magnetic joint 1021. The main hybrid joint 102 further includes a first positioning member 1022. The first combining device 11 has at least one first hybrid joint 110, and the first hybrid joint 110 includes an electrical contact 1100 and a magnetic joint 1101. The first hybrid joint 110 further includes a second positioning member 1102. The second positioning member 1102 is capable of being positioned relative to the first positioning member 1022 to bring about accurate electrical coupling when joined to the main body 10. The second combining device 12 has at least one second hybrid joint 120, and the second hybrid joint 120 includes an electrical contact 1200 and a magnetic joint 1201. The second hybrid joint 120 further includes a third positioning member 1202. The third positioning member 1202 is capable of being positioned relative to the first positioning member 1022 or the second positioning member 1102 to bring about accurate electrical coupling when joined to the main body 10 or the first combining device 11. The main body 10 is joined to the externally connected devices (11 and 12) through the magnetic joints (1021, 1101, and 1201) and the positioning members (1022, 1102, and 1202). The main body 10 is closely joined to the externally connected devices (11 and 12) or the externally connected devices (11 and 12) are closely joined to each other on a specific relative position through the positioning members (1022, 1102, and 1202), such that the electrical contacts (1020, 1100, and 1200) may accurately and correspondingly contact with one another. Therefore, the externally connected devices and the main body 10 may not easily be detached from one another when falling onto the ground, and even if a detachment does occur by accident due to fall-off, these devices may be joined again through the magnetic joints (1021, 1101, and 1201). Signal transmission can be performed between the main body 10 and the externally connected devices (11 and 12) or between the externally connected devices (11 and 12) through the electrical contacts (1020, 1100, and 1200).

One or more sets of hybrid joints may be disposed on the main body 10, the first combining device 11, and the second combining device 12 upon actual requirements. In an example, according to different requirements, the main body 10 is magnetically joined to and electrically coupled through the main hybrid joint 102 thereof to the first combining device 11 or the second combining device 12. In another example, the first combining device 11 and the second combining device 12 are first magnetically joined to and electrically coupled to each other through the first hybrid joint 110 and the second hybrid joint 120, and then magnetically joined to and electrically coupled to the main hybrid joint 102 of the main body 10. The main body 10 receives and transmits a control instruction to the processor to control the first combining device 11 or the second combining device 12, and the first combining device 11 or the second combining device 12 may also perform signal transmission with the main body 10 through the electrical contacts (1020, 1100, and 1200).

The communication device with replaceable function modules of the present invention may be a mobile phone or a personal digital assistant (PDA). The main body 10, the first combining device 11, and the second combining device 12 are joined by means of lap joint.

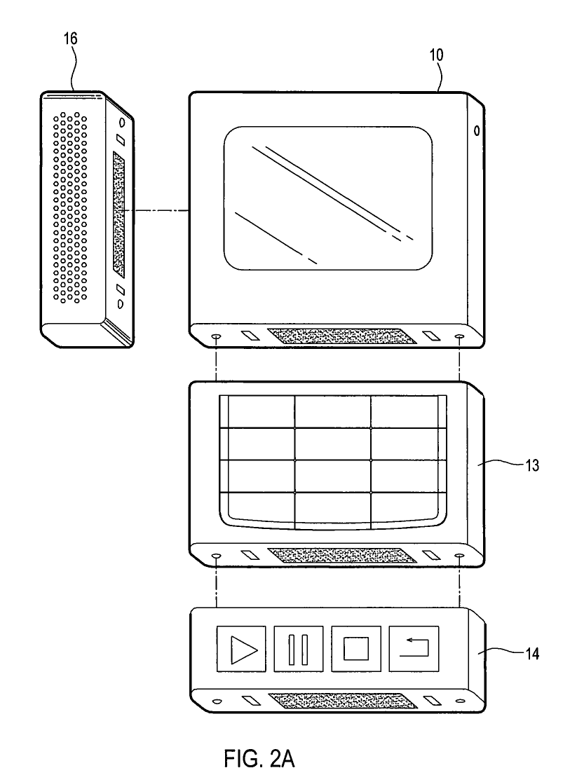

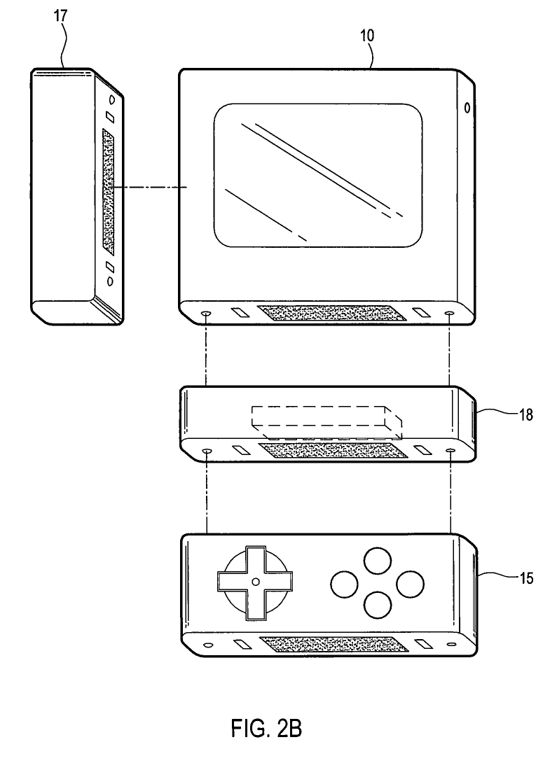

FIGS. 2A and 2B are schematic views of externally connected devices of a mobile communication device with replaceable function modules according to an embodiment of the present invention. Referring to FIGS. 2A and 2B, the first combining device or the second combining device may be a press-key panel 13, a multimedia playing controller 14, a game controller 15, a loudspeaker 16, a memory expansion device 17, or a second electric power supply device 18. As shown in FIG. 2A, in this embodiment, the press-key panel 13 and the multimedia playing controller 14 are magnetically joined to and electrically coupled to each other through the hybrid joints, another hybrid joint of the press-key panel 13 is magnetically joined to and electrically coupled to the main body 10, and another main hybrid joint of the main body 10 is magnetically joined to and electrically coupled to the loudspeaker 16.

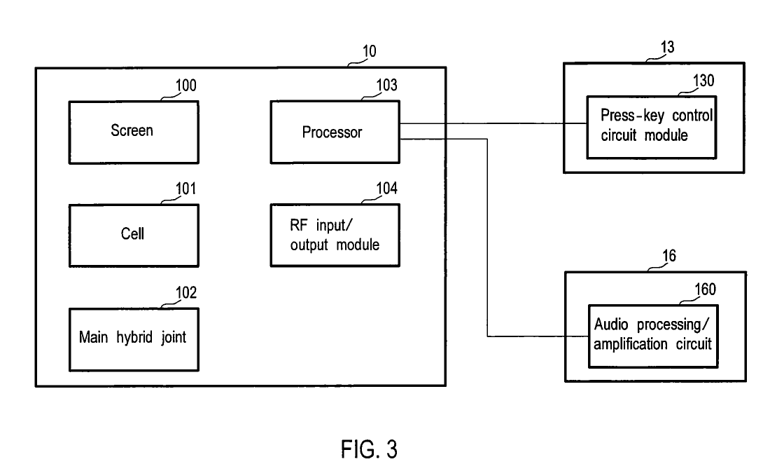

FIG. 3 is a block diagram of a mobile communication device with replaceable function modules according to an embodiment of the present invention. In FIG. 3, in addition to the screen 100, the cell 101, and the main hybrid joint 102, the main body 10 further includes a processor 103 and a radio frequency (RF) input/output module 104. The first combining device 11 or the second combining device 12 has different functional modules according to the functions. For example, the first combining device 11 or the second combining device 12, being the press-key panel 13, has a press-key control circuit module 130, and has an audio processing/amplification circuit 160 for being the loudspeaker 16.

When not joined to any externally connected device, the mobile communication device with replaceable function modules of the present invention may operate through the working module of the main body 10. The main body 10 receives and transmits a control instruction to the processor to control the operation of the main body 10. For example, a number is dialed through the touch panel of the screen 100. Then, the processor 103 controls the RF input/output module 104 to emit a signal so as to make a call, or the RF input/output module 104 receives a signal encoded/decoded by the processor 103 so as to receive a call. When the main body 10 is joined to an externally connected device, the processor 103 activates the functional module of the externally connected device to make the externally connected device operate.

In view of the above, the mobile communication device with replaceable function modules of the present invention is divided into a plurality of different members, and is coupled to different devices through the peripherally arranged hybrid joints on the main body 10 thereof as the central member. One or more externally connected devices may be coupled according to actual requirements. When coupled to different devices, the main body 10 activates the functional module corresponding to the individual externally connected device. In addition, by using the magnetic joint, the mobile communication device may not be separated after falling onto the ground, thereby preventing the unavailability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A mobile communication device with replaceable function modules, comprising:
a main body, having a screen, a processor, a radio frequency (RF) input/output module, and at least one main hybrid joint, wherein the screen, the RF input/output module, and the main hybrid joint are coupled to the processor, and the main hybrid joint comprises a first electrical contact and a first magnetic joint; and
a first combining device, having at least one first hybrid joint comprising a second electrical contact and a second magnetic joint, wherein the first hybrid joint is magnetically joined to and electrically coupled to the main body.

2. The mobile communication device with replaceable function modules according to claim 1, wherein the main hybrid joint further comprises a first positioning member.

3. The mobile communication device with replaceable function modules according to claim 2, wherein the first hybrid joint further comprises a second positioning member capable of being positioned relative to the first positioning member to bring about accurate electrical coupling when joined to the main body.

4. The mobile communication device with replaceable function modules according to claim 3, further comprising a second combining device having at least one second hybrid joint comprising a third electrical contact, a third magnetic joint, and a third positioning member, wherein the third positioning member is capable of being positioned relative to the first positioning member or the second positioning member to bring about accurate electrical coupling when joined to the main body or the first combining device.

5. The mobile communication device with replaceable function modules according to claim 4, wherein the first combining device or the second combining device comprises a press-key panel, a multimedia playing controller, a game controller, a loudspeaker, a memory expansion device, or an electric power supply.

6. The mobile communication device with replaceable function modules according to claim 1, wherein the main body receives and transmits a control instruction to the processor to control the main body or the first combining device.

7. The mobile communication device with replaceable function modules according to claim 6, wherein the main body receives the control instruction through the screen.

8. The mobile communication device with replaceable function modules according to claim 1, further comprising a second combining device having at least one second hybrid joint comprising a third electrical contact and a third magnetic joint, wherein the second hybrid joint is magnetically joined to and electrically coupled to the main body or the first combining device.

9. The mobile communication device with replaceable function modules according to claim 8, wherein the main body, the first combining device, and the second combining device are joined and coupled by means of lap joint.

10. The mobile communication device with replaceable function modules according to claim 1, wherein the main body further comprises a cell for providing electric power.

11. The mobile communication device with replaceable function modules according to claim 1, wherein the mobile communication device comprises a mobile phone or a personal digital assistant (PDA).

12. The mobile communication device with replaceable function modules according to claim 1, wherein the screen comprises a touch panel.

13. A mobile communication device with replaceable function modules, comprising:
a main body, having a screen, a processor, a radio frequency (RF) input/output module, and at least one main hybrid joint, wherein the screen, the RF input/output module, and the main hybrid joint are coupled to the processor, and the main hybrid joint comprises a first electrical contact, a first magnetic joint, and a first positioning member;
a first combining device, having at least one first hybrid joint comprising a second electrical contact, a second magnetic joint, and a second positioning member, wherein the first hybrid joint is magnetically joined to and electrically coupled to the main body; and
a second combining device, having at least one second hybrid joint comprising a third electrical contact, a third magnetic joint, and a third positioning member, wherein the second hybrid joint is magnetically joined to and electrically coupled to the main body or the first combining device.

14. The mobile communication device with replaceable function modules according to claim 13, wherein the main body receives and transmits a control instruction to the processor to control the main body, the first combining device, or the second combining device.

15. The mobile communication device with replaceable function modules according to claim 14, wherein the main body receives the control instruction through the screen.

16. The mobile communication device with replaceable function modules according to claim 13, wherein the main body, the first combining device, and the second combining device are joined and coupled by means of lap joint.

17. The mobile communication device with replaceable function modules according to claim 13, wherein the main body further comprises a cell for providing electric power.

18. The mobile communication device with replaceable function modules according to claim 13, wherein the first combining device or the second combining device comprises a press-key panel, a multimedia playing controller, a game controller, a loudspeaker, a memory expansion device, or an electric power supply.

19. The mobile communication device with replaceable function modules according to claim 13, wherein the screen comprises a touch panel.

20. A mobile communication device with replaceable function modules, comprising a main body having a screen, a processor, and a radio frequency (RF) input/output module, wherein the screen and the RF input/output module are coupled to the processor, and the mobile communication device is characterized by the following:
wherein the main body further comprises at least one main hybrid joint coupled to the processor, and the main hybrid joint comprises an electrical contact for transmitting signals and a magnetic joint with magnetic properties.

21. The mobile communication device with replaceable function modules according to claim 20, wherein the main hybrid joint further comprises a positioning member capable of being positioned relative to other functional modules.

22. The mobile communication device with replaceable function modules according to claim 20, wherein the main body further comprises a cell for providing electric power.

23. The mobile communication device with replaceable function modules according to claim 20, wherein the main body receives and transmits a control instruction to the processor to control the main body.

24. The mobile communication device with replaceable function modules according to claim 23, wherein the main body receives the control instruction through the screen.

25. The mobile communication device with replaceable function modules according to claim 20, wherein the screen comprises a touch panel.
